(19) United States
(12) Patent Application Publication
(10) Pub. No.: US 2016/0191018 A1
(43) Pub. Date: Jun. 30, 2016

(54) APPARATUS FOR ATTENUATION USING FINE TUNING FUNCTION

(71) Applicant: Eelctronics and Telecommunications Research Institute, Daejeon (KR)

(72) Inventors: Jin Cheol JEONG, Daejeon (KR); In Bok YOM, Daejeon (KR)

(21) Appl. No.: 14/948,957

(22) Filed: Nov. 23, 2015

(30) Foreign Application Priority Data
Dec. 31, 2014 (KR) 10-2014-0195020

(51) Int. Cl. H03H 11/24

(52) U.S. Cl. CPC H03H 11/245

(57) ABSTRACT

Provided is a digital attenuation apparatus using a fine tuning function of an attenuation value, which includes: a plurality of digital attenuators connected in series; and an integrated attenuator finely attenuating the attenuation value when output values of the plurality of digital attenuators are input.

### CROSS-REFERENCE TO RELATED APPLICATIONS

This application claims priority to and the benefit of Korean Patent Application No. 10-2014-000195020 filed in the Korean Intellectual Property Office on Dec. 31, 2014, the entire contents of which are incorporated herein by reference.

### TECHNICAL FIELD

The present invention relates to a digital attenuation apparatus, and more particularly, to a digital attenuation apparatus using a fine tuning function.

### BACKGROUND ART

In recent years, as an antenna system, a simple/manual antenna has been changed to a complicated/active antenna. Therefore, the need for an active phase array antenna system has rapidly increased. The active phase array antenna needs an RF component that can digitally control a magnitude and a phase of a signal in an antenna. The component that can digitally control the magnitude of the signal as described above is a digital attenuation apparatus.

The digital attenuation apparatus may implement a required attenuation value by connecting a plurality of digital attenuation apparatuses corresponding to each bit in series. Since respective sections are digitally combined to acquire various attenuation values, the digital attenuation apparatus is called a digital variable attenuation apparatus.

However, values which are equal to or less than a minimum attenuation value may be required for minute tuning of the attenuation value while operating the system and the digital attenuation apparatus has a disadvantage in that a value equal to or less than the minimum attenuation value cannot be implemented unlike an analog attenuation apparatus.

### SUMMARY OF THE INVENTION

The present invention has been made in an effort to provide a digital attenuation apparatus using a fine tuning function of an attenuation value, which integrally implements an analog attenuation function in the digital attenuation apparatus.

An exemplary embodiment of the present invention provides a digital attenuation apparatus using a fine tuning function of an attenuation value including: a plurality of digital attenuators connected in series; and an integrated attenuator finely tuning the attenuation value when output values of the plurality of digital attenuators are input.

The plurality of digital attenuators may have different attenuation values.

The plurality of digital attenuators may include a first digital attenuator having a first attenuation value, a second digital attenuator having a second attenuation value larger than the first attenuation value, and a third digital attenuator having a third attenuation value larger than the second attenuation value.

The integrated attenuator may include a first switch unit connected to an input terminal to select a reference path or an attenuation path, a second switch unit connected to an output terminal to select an output from the reference path or attenuation path, a resistor unit provided on the attenuation path to attenuate an input signal as large as a resistance value, an off-state variable resistor unit variable by control voltage when the reference path is selected, and an on-state variable resistor unit variable by the control voltage when the attenuation path is selected.

The off-state variable resistor unit may include a field effect transistor (FET) element in which channel resistance varies by the control voltage applied to a gate when the reference path is selected by the first switch unit and the second switch unit, and a voltage source applying the control voltage to the FET element.

The off-state variable resistor unit may further include a stabilization unit connected to a gate of the FET element to stabilize voltage applied to the gate.

The FET element may include a drain connected to the reference path, a source connected to a ground voltage terminal, and a gate connected to the stabilization unit.

The on-state variable resistor unit may include an FET element in which channel resistance varies by the control voltage applied to the gate when the attenuation path is selected by the first switch unit and the second switch unit, and a voltage source applying the control voltage to the FET element.

The on-state variable resistor unit may further include a stabilization unit connected to the gate of the FET element to stabilize the voltage applied to the gate.

The FET element includes a drain connected to the attenuation path, a source connected to the ground voltage terminal, and a gate connected to the stabilization unit.

The resistor unit may include a first resistor having a fixed resistance value and provided between an input terminal and an output terminal, a second resistor having the fixed resistance value and connected with the first resistor in series, and a third resistor connected between the first resistor and the second resistor in a T shape.

The on-state variable resistor unit may be connected with the third resistor in parallel.

The first switch unit includes a first FET element in which a drain is connected to the input terminal and a source is connected to the reference path, and a second FET element in which a drain is connected to the input terminal commonly with the first FET and a source is connected to the attenuation path.

The second switch unit may include a third FET element in which a drain is connected to the reference path and a source is connected to the output terminal, and a fourth FET element in which a drain is connected to the attenuation path and a source is connected to the output terminal.

When the first FET element and the third FET element are turned on, an input signal may be applied to the reference path and when the second FET element and the fourth FET element are turned on, the input signal may be applied to the attenuation path.

According to an exemplary embodiment of the present invention, an analog attenuation function is added to a digital attenuation apparatus to provide both easiness and accuracy of control of the digital attenuation apparatus and a fine tuning function of an analog attenuation apparatus.

The exemplary embodiments of the present invention are illustrative only, and various modifications, changes, substitutions, and additions may be made without departing from the technical spirit and scope of the appended claims by those skilled in the art, and it will be appreciated that the modifications and changes are included in the appended claims.

### BRIEF DESCRIPTION OF THE DRAWINGS

FIG. 1 is a configuration diagram of a 4-bit digital attenuation apparatus according to an exemplary embodiment of the present invention.

FIG. 2 is a detailed configuration diagram of an integrated 8-dB attenuator having the fine tuning function of FIG. 1.

FIG. 3 is a detailed circuit diagram of the integrated attenuator of FIG. 1.

FIG. 4 is a graph illustrating a fine tuning simulation result in turning on/off the integrated attenuator according to the exemplary embodiment of the present invention.

It should be understood that the appended drawings are not necessarily to scale, presenting a somewhat simplified representation of various features illustrative of the basic principles of the invention. The specific design features of the present invention as disclosed herein, including, for example, specific dimensions, orientations, locations, and shapes will be determined in part by the particular intended application and use environment.

In the figures, reference numbers refer to the same or equivalent parts of the present invention throughout the several figures of the drawing.

### DETAILED DESCRIPTION

Hereinafter, in order to describe the present invention in detail so as for those skilled in the art to easily carry out the technical spirit of the present invention, exemplary embodiments of the present invention will be described with reference to the accompanying drawings.

The present invention provides an integrated attenuation apparatus structure acquired by combining an analog attenuation function with a digital attenuation apparatus. Such an integration structure may implement both an advantage of easiness and accuracy of a control which is an advantage of the digital attenuation apparatus and an advantage of fine tuning of an attenuation value of an analog attenuation apparatus. To this end, in the present invention, for the fine tuning, predetermined voltage or higher is applied to gate voltage of a field effect transistor (FET), and as a result, the integrated structure is driven as the analog attenuation apparatus and when the integrated structure is driven as the digital attenuation apparatus, very low negative voltage (e.g., −2 V) is applied to a gate of the FET to remove the function of the analog attenuation apparatus.

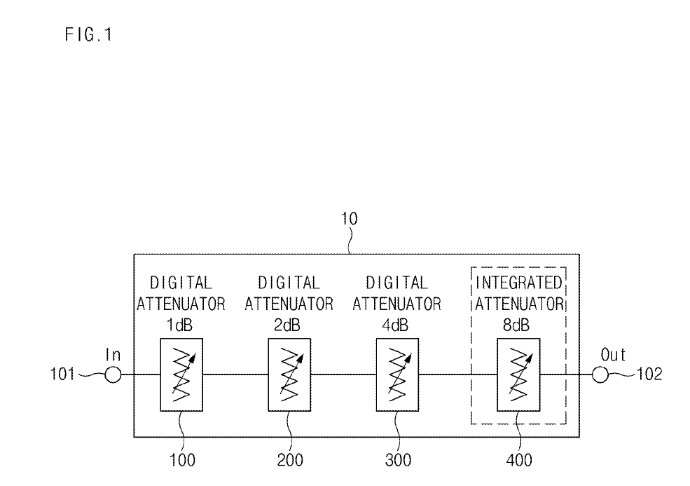

Hereinafter, exemplary embodiments of the present invention will be described in detail with reference to FIGS. 1 to 4.

FIG. 1 is a configuration diagram of a 4-bit digital attenuation apparatus 10 according to an exemplary embodiment of the present invention. In the present invention, a 4-bit digital attenuation apparatus is disclosed as an example, but the digital attenuation apparatus may be implemented in various plural bits including 6 bits, 8 bits, and the like. Further, when a plurality of digital attenuators are connected in series, a digital attenuator having a largest attenuation value of a last bit may be designed to have an analog tuning function.

Referring to FIG. 1, the 4-bit digital attenuation apparatus according to the exemplary embodiment of the present invention includes a digital attenuator 100 having an attenuation value of 1 dB, a digital attenuator 200 having an attenuation value of 2 dB, a digital attenuator 300 having an attenuation value of 4 dB, and an integrated attenuator 400 having an attenuation value of 8 dB.

The digital attenuator 100 is a general digital attenuator that attenuates an input signal by 1 dB, the digital attenuator 200 is a general digital attenuator that attenuates the input signal by 2 dB, and the digital attenuator 300 is a general digital attenuator that attenuates the input signal by 4 dB.

The integrated attenuator 400 is an integrated attenuator that may achieve fine tuning of the attenuation value by combining a digital attenuation function and an analog attenuation function.

The 4-bit digital attenuation apparatus according to the exemplary embodiment of the present invention, which has such a configuration, may make a total of 16 attenuation characteristics of 0 to 15 dB (for each 1 dB step) between an input 101 and an output 102 of the digital attenuation apparatus through respective on/off combinations of three digital attenuators 100, 200, and 300 and one integrated attenuator 400.

The general digital attenuator may not make a fine attenuation value among the respective steps, but the analog attenuator may make the fine minute value among the respective steps.

For example, when the digital attenuator is constituted by four digital attenuators having the attenuation values of 1, 2, 4, and 8 dB, four values are combined to be variable from 1 to 15 dB by a step of 1 dB. For example, in order to implement 3 dB, when only the 1-dB and 2-dB attenuators are turned on, a 3 (1+2)-dB attenuation apparatus may be implemented. Further, since a sum of combining all of the respective sections becomes a total attenuation value, a high attenuation value may be implemented by combining various attenuation apparatuses.

In the present invention, the plurality of digital attenuators 100, 200, and 300 and the integrated attenuator 400 at a last stage are provided to enable the fine tuning. That is, in the present invention, an analog fine tuning function is performed through the integrated attenuator 400 to make the values among the respective steps into desired attenuation values by an analog scheme.

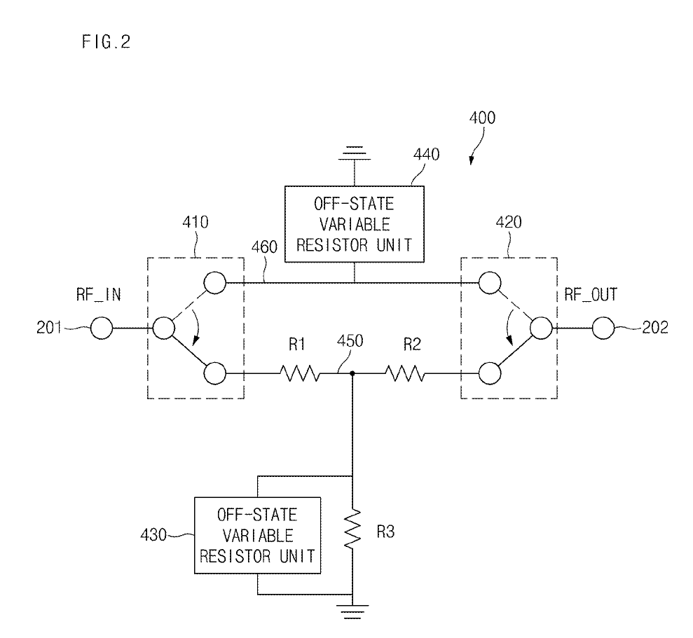

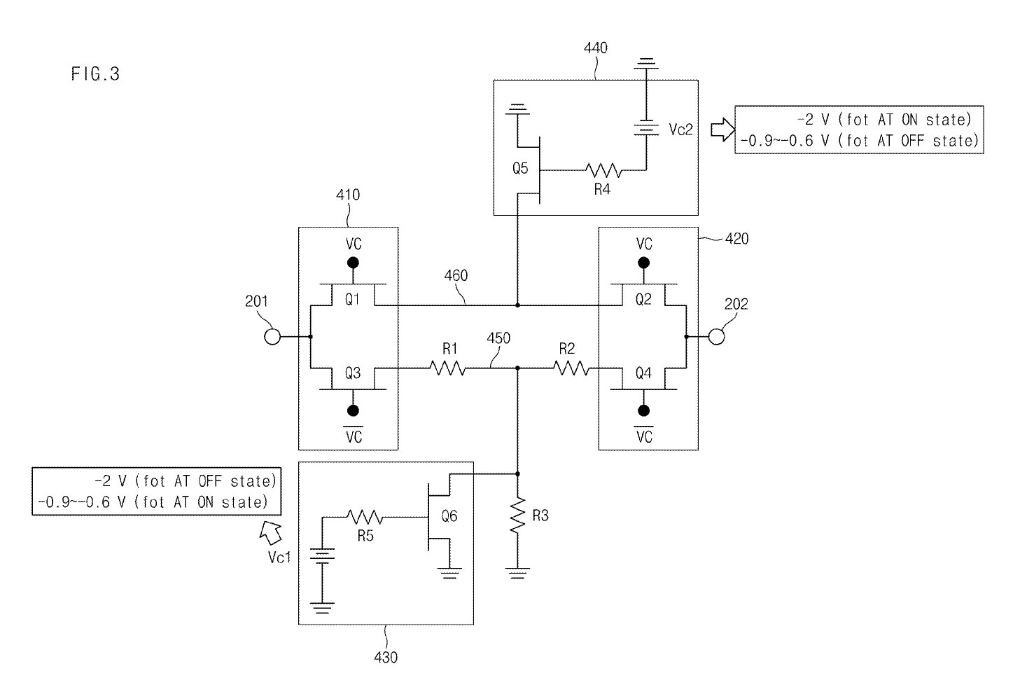

FIG. 2 is a detailed configuration diagram of an integrated attenuator 400 having the fine tuning function of FIG. 1. FIG. 3 is a detailed circuit diagram of the integrated attenuator 400.

Hereinafter, a detailed configuration and operation of the integrated attenuator 400 according to the present invention will be described in detail with reference to FIGS. 2 and 3.

Referring to FIG. 2, the integrated attenuator 400 includes switch units 410 and 420, resistors R1, R2, and R3, an on-state variable resistor unit 430, and an off-state variable resistor unit 440.

The integrated attenuator 400 includes two paths between an input terminal 201 and an output terminal 202, that is, an attenuation path 450 and a reference path 460. In the attenuation path 450, the resistors R1, R2, and R3 that determine the attenuation value and the on-state variable resistor unit 430 which is a variable resistor are deployed between the output terminal 201 and the output terminal 202 and the reference path 460 is deployed on a line including the off-state variable resistor unit 440 which is the variable resistor without a fixed resistor. In this case, the attenuation value is determined by a ratio of an insertion loss of the attenuation path 450 to an insertion loss of the reference path 460. Each one switch unit 410 or 420 is connected to the input terminal 201 and the output terminal 202 of both paths 450 and 460 to determine one of both paths 450 and 460.

The switch unit 410 as a single pole double thru (SPDT) switch is provided at the input terminal 201 to select whether to send an input signal RF_IN through the attenuation path 450 or the reference path 460. In this case, referring to FIG. 3, the switch unit 410 includes switches Q1 and Q3 in which a drain is commonly connected to the input terminal 201 and a source is connected to each of the reference path 460 and the attenuation path 450. In this case, the switches Q1 and Q3 are configured by field effect transistors (FETs) and controlled by gate voltage VC. That is, when the reference path 460 is selected, the switch Q1 is turned on and the switch Q3 is turned off and when the attenuation path 450 is selected, the switch Q1 is turned off and the switch Q3 is turned on. The source of the switch Q3 is connected to one side of the resistor R1.

The switch unit 420 is provided at the output terminal 202 to select whether to send a signal of the attenuation path 450 or a signal of the reference path 460 as an output signal RF_OUT. In this case, referring to FIG. 3, the switch unit 420 includes switches Q2 and Q4 in which the source is commonly connected to the output terminal 202 and the drain is connected to each of the reference path 460 and the attenuation path 450. In this case, the switches Q2 and Q4 are configured by the field effect transistors (FETs) and controlled by the gate voltage VC. That is, when the reference path 460 is selected, the switch Q2 is turned on and the switch Q4 is turned off and when the attenuation path 450 is selected, the switch Q2 is turned off and the switch Q4 is turned on. The drain of the switch Q4 is connected to one side of the resistor R2.

The resistors R1, R2, and R3 are deployed between the switch unit 410 and the switch unit 420 in a T shape and have fixed resistance values. The resistor R3 is connected with the on-state variable resistor unit 430 in parallel. In the present invention, the resistors R1 and R2 are configured to have the same resistance value. In this case, only one or two resistors provided on the attenuation path 450 may be deployed in series, but the resistors are implemented in the T shape in the present invention in order to implement a large attenuation value.

The on-state variable resistor unit 430 is variable by control voltage when the integrated attenuator 400 is turned on by digital control. When the integrated attenuator 400 is turned on, the 4-bit digital attenuator 10 may make not inconsecutive values of 1 dB step but consecutive attenuation values from 8 to 16 dB. The consecutive attenuation values are used in the fine tuning. In this case, referring to FIG. 3, the on-state variable resistor unit 430 includes an FET Q6, a resistor R5, and power voltage Vc1. The FET Q6 is the FET and a drain is connected to one side of the resistor R3, a source is connected to a ground voltage terminal, and a gate is connected to one side of the resistor R5. The resistor R5 and the power source Vc1 are, in series, connected between the gate and the ground voltage terminal of the FET Q6. In this case, when the power source Vc1 is turned on, voltage of −0.9 V to −0.6 V is applied to the power source Vc1 and when the power source Vc1 is turned off, voltage of −2 V is applied to the power source Vc1. In this case, the resistor R5 has a large resistance value of several kiloohm and is provided for stable supply of the power source Vc1.

The off-state variable resistor unit 440 is variable by the control voltage when the integrated attenuator 400 is turned off by the digital control. When the integrated attenuator 400 is turned off, the 4-bit digital attenuator 10 may make consecutive attenuation values from 0 to 8 dB. The consecutive attenuation values are used in the fine tuning. In this case, referring to FIG. 3, the off-state variable resistor unit 440 includes an FET Q5, a resistor R4, and a power source Vc2. The FET Q5 is the FET and a drain is connected to the reference path 460, and a source is connected to the ground voltage terminal and controlled by an output value of the resistor R4. The resistor R4 is a fixed resistance value and when the power source Vc2 is turned off, voltage of −0.9 V to −0.6 V is applied to the power source Vc2 and when the power source Vc2 is turned on, voltage of −2 V is applied to the power source Vc2. In this case, the resistor R4 has the large resistance value of several kohms and is provided for stable supply of the power source Vc2.

The integrated attenuator 400 having the configuration may be in on and off states by the digital control. When the integrated attenuator 400 is turned on, the 4-bit digital attenuator 10 makes values of 8 to 15 dB (1 dB step) and when the integrated attenuator 400 is turned off, the 4-bit digital attenuator 10 makes values of 0 to 7 dB (1 dB step). The operation will be described below in detail.

One of the attenuation path 450 and the reference path 460 is selected by the switch units 410 and 420. When the switches Q1 and Q2 are turned on and the switches Q3 and Q4 are turned off, the reference path 460 is selected and when the switches Q1 and Q2 are turned off and the switches Q3 and Q4 are turned on, the attenuation path 450 is selected. The input signal RF_IN input through the input terminal 201 is input into one of the attenuation path 450 and the reference path 460 to be output to the output terminal 202 according to operations of the switch units 410 and 420. That is, when an on signal is input into the integrated attenuator 400, the attenuation path 450 is selected and when an off signal is input into the integrated attenuator 400, the reference path 460 is selected.

When the off signal is applied to the integrated attenuator 400, and as a result, the reference path 460 is selected, the FET Q5 is controlled to have a variable resistance value.

That is, the FETs Q5 and Q6 apply the control voltage Vc1 and Vc2 to gates thereof to continuously change channel resistance between a drain and a source. For example, when gate voltage of the FET Q5 or FET Q6 is changed from −0.9 to −0.6 V, resistance between the drain and the gate is changed from a high value to a low value. On the contrary, when gate voltage of −2 V is applied to the gate of the FET Q5 or FET Q6, resistance between the drain and the source is very large (almost opened state), and as a result, the resistance may not serve as the resistance.

When the integrated attenuator 400 is turned off, that is, the reference path 460 is selected, the 4-bit digital attenuation apparatus 10 of FIG. 1 operates at 0 to 7 dB (1 dB step) by combining the digital attenuator 100 having the attenuation value of 1 dB, the digital attenuator 200 having the attenuation value of 2 dB, and the digital attenuator 300 having the attenuation value of 4 dB. In this case, since the integrated attenuator 400 may make consecutive values of 0 to 1 dB by control of the FET Q5, the 4-bit digital attenuation apparatus 10 may make consecutive attenuation characteristics of 0 to 8 dB.

On the contrary, when the integrated attenuator 400 is turned on, that is, the attenuation path 450 is selected, the 4-bit digital attenuation apparatus 10 of FIG. 1 operates at 8 to 15 dB (1 dB step) by combining the digital attenuator 100 having the attenuation value of 1 dB, the digital attenuator 200 having the attenuation value of 2 dB, and the digital attenuator 300 having the attenuation value of 4 dB. In this case, since the integrated attenuator 400 may make consecutive attenuation values of 8 to 9 dB by control of the FET Q6, the 4-bit digital attenuation apparatus 10 may make consecutive attenuation characteristics of 8 to 16 dB.

Accordingly, the 4-bit digital attenuator 10 may have consecutive attenuation characteristics of 0 to 16 dB due to the integrated attenuator 400 using analog fine tuning of the present invention.

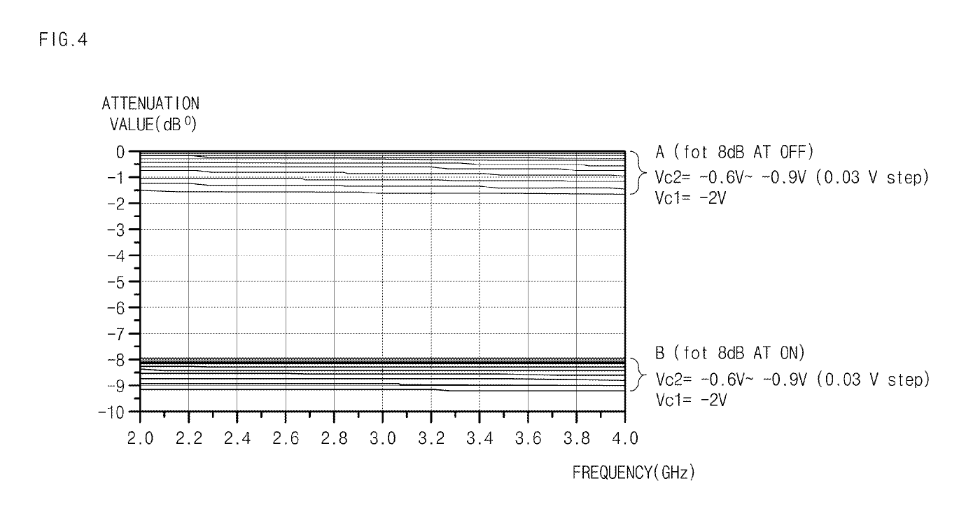

FIG. 4 is a graph illustrating a fine tuning simulation result in turning on/off the integrated attenuator according to the exemplary embodiment of the present invention.

Referring to FIG. 4, when the digital attenuator 100 having the attenuation value of 1 dB, the digital attenuator 200 having the attenuation value of 2 dB, and the digital attenuator 300 having the attenuation value of 4 dB are turned off, the integrated attenuator 400 having the attenuation value of 8 dB of the present invention may know a digital attenuation characteristic when being turned on/off.

“A” in the FIG. 4 shows an attenuation characteristic between the input terminal 201 and the output terminal 202 when the integrated attenuator 400 is turned off, the reference path is selected and the voltage of −0.9 to −0.6 V is variably applied to the gate of the FET Q5. When the gate voltage of the FET Q5 is −0.9 V, a channel resistance value of the FET Q5 is large, and as a result, the FET Q5 may not serve as the resistor. On the contrary, when the gate voltage of the FET Q5 is changed to 0 V, the channel resistance of the FET Q5 gradually decreases to serve to consecutively increase the resistance of the reference path 460, thereby increasing the attenuation value of the reference path. In this case, the FET Q6 positioned on the attenuation path 450 is set to −2 V to have a very large channel resistance value. Therefore, it may be found that when the integrated attenuator 400 is turned off, the attenuation characteristics of 0 to 1 dB may be consecutively controlled.

“B” in the FIG. 4 shows an attenuation characteristic between the input terminal 201 and the output terminal 202 when the integrated attenuator 400 is turned on, the attenuation path 450 is selected and the voltage of −0.9 to −0.6 V is variably applied to the gate of the FET Q6. When the gate voltage of the FET Q6 is set to −0.9 V, the channel resistance of the FET Q6 is very large not to influence the value of the integrated attenuator. When the gate voltage of the FET Q6 is changed to 0 V, the channel resistance of the FET Q6 gradually decreases. In this case, among the T-shaped resistor components, resistance of R3 and a parallel FET Q6 decreases.

Therefore, a total value of the T-shaped resistor constituted by the resistor R1, the resistor R2, and the resistor R3, and the FET Q6 increases to thereby increase the attenuation value of the attenuator. In this case, the FET Q5 positioned on the reference path 460 is set to −2 V to have a very large channel resistance value. Therefore, it may be found that when the integrated attenuator 400 is turned on, the attenuation characteristics of 8 to 9 dB may be consecutively controlled.

As described above, the present invention provides the digital attenuation apparatus circuit having the fine tuning function required in the system by adding the analog attenuation function to the digital attenuation apparatus. In the circuit, since the FET is connected to the fixed resistor used in the digital attenuation apparatus in parallel, the channel resistance of the FET is changed by the gate voltage to enable the attenuation value of the digital attenuation apparatus to be finely tuned.

Therefore, such a structure of the present invention may implement the fine tuning required in the system by the analog function with easiness and accuracy of the control which is an advantage of the digital attenuation apparatus.

Further, the integrated attenuator 400 is implemented by just adding the FET serving as the analog attenuation function to the digital attenuation apparatus to reduce area consumption and cost consumption as compared with a case in which the digital attenuator and the analog attenuator are separately provided.

The exemplary embodiments of the present invention are illustrative only, and various modifications, changes, substitutions, and additions may be made without departing from the technical spirit and scope of the appended claims by those skilled in the art, and it will be appreciated that the modifications and changes are included in the appended claims.

What is claimed is:

1. A digital attenuation apparatus using a fine tuning function of an attenuation value, the apparatus comprising:
a plurality of digital attenuators connected in series; and
an integrated attenuator finely tuning the attenuation value when output values of the plurality of digital attenuators are input.

2. The apparatus of claim 1, wherein the plurality of digital attenuators has different attenuation values.

3. The apparatus of claim 1, wherein:
the plurality of digital attenuators includes
a first digital attenuator having a first attenuation value,
a second digital attenuator having a second attenuation value larger than the first attenuation value, and
a third digital attenuator having a third attenuation value larger than the second attenuation value.

4. The apparatus of claim 1, wherein:
the integrated attenuator includes
a first switch unit connected to an input terminal to select a reference path or an attenuation path,
a second switch unit connected to an output terminal to select an output from the reference path or attenuation path,
a resistor unit provided on the attenuation path to attenuate an input signal as large as a resistance value,
an off-state variable resistor unit variable by control voltage when the reference path is selected, and
an on-state variable resistor unit variable by the control voltage when the attenuation path is selected.

5. The apparatus of claim 4, wherein:
the off-state variable resistor unit includes
a field effect transistor (FET) element in which channel resistance varies by the control voltage applied to a gate when the reference path is selected by the first switch unit and the second switch unit, and
a voltage source applying the control voltage to the FET element.

6. The apparatus of claim 5, wherein: the off-state variable resistor unit further includes a stabilization unit connected to a gate of the FET element to stabilize voltage applied to the gate.

7. The apparatus of claim 5, wherein:
the FET element includes
a drain connected to the reference path,
a source connected to a ground voltage terminal, and
a gate connected to the stabilization unit.

8. The apparatus of claim 4, wherein:
the on-state variable resistor unit includes
an FET element in which channel resistance varies by the control voltage applied to the gate when the attenuation path is selected by the first switch unit and the second switch unit, and
a voltage source applying the control voltage to the FET element.

9. The apparatus of claim 8, wherein the on-state variable resistor unit further includes a stabilization unit connected to the gate of the FET element to stabilize the voltage applied to the gate.

10. The apparatus of claim 8, wherein:
the FET element includes
a drain connected to the attenuation path,
a source connected to the ground voltage terminal, and
a gate connected to the stabilization unit.

11. The apparatus of claim 4, wherein:
the resistor unit includes
a first resistor having a fixed resistance value and provided between an input terminal and an output terminal,
a second resistor having the fixed resistance value and connected with the first resistor in series, and
a third resistor connected between the first resistor and the second resistor in a T shape.

12. The apparatus of claim 11, wherein the on-state variable resistor unit is connected with the third resistor in parallel.

13. The apparatus of claim 4, wherein:
the first switch unit includes
a first FET element in which a drain is connected to the input terminal and a source is connected to the reference path, and
a second FET element in which a drain is connected to the input terminal commonly with the first FET and a source is connected to the attenuation path.

14. The apparatus of claim 13, wherein:
the second switch unit includes
a third FET element in which a drain is connected to the reference path and a source is connected to the output terminal, and
a fourth FET element in which a drain is connected to the attenuation path and a source is connected to the output terminal.

15. The apparatus of claim 14, wherein when the first FET element and the third FET element are turned on, an input signal is applied to the reference path and when the second FET element and the fourth FET element are turned on, the input signal is applied to the attenuation path.
